(19) United States
(12) Patent Application Publication
(10) Pub. No.: US 2024/0263003 A1
(43) Pub. Date: Aug. 8, 2024

(54) RESIN COMPOSITION, PREPREG USING SAME, FILM PROVIDED WITH RESIN, METAL FOIL PROVIDED WITH RESIN, METAL-CLAD LAMINATE, AND WIRING BOARD

(71) Applicant: PANASONIC INTELLECTUAL PROPERTY MANAGEMENT CO., LTD., Osaka (JP)

(72) Inventors: Yasunori NISHIGUCHI, Osaka (JP); Hirosuke SAITO, Osaka (JP)

(73) Assignee: PANASONIC INTELLECTUAL PROPERTY MANAGEMENT CO., LTD., Osaka (JP)

(21) Appl. No.: 18/561,591

(22) PCT Filed: May 16, 2022
(86) PCT No.: PCT/JP2022/020366

§ 371 Date: Nov. 16, 2023

(30) Foreign Application Priority Data
May 17, 2021 (JP) 2021-083148

(51) Int. Cl. C08L 53/00; C08J 5/24; C08K 3/36; C08K 5/49; C08L 25/04; C08L 25/08; C08L 65/00; H05K 1/03

(52) U.S. Cl. CPC C08L 53/005; C08J 5/24; C08K 3/36; C08K 5/49; C08L 25/04; C08L 25/08; C08L 65/00; H05K 1/038; C08J 2325/08; C08J 2365/00; C08J 2425/08; C08J 2465/00

(57) ABSTRACT

An aspect of the present invention relates to a resin composition containing a hydrocarbon-based compound (A) represented by the following Formula (1) [In Formula (1), X represents a hydrocarbon group having 6 or more carbon atoms and containing at least one selected from an aromatic cyclic group or an aliphatic cyclic group, and n represents an integer from 1 to 10]; and a styrenic polymer (B) that is solid at 25° C. and is different from the hydrocarbon-based compound (A).

### TECHNICAL FIELD

The present invention relates to a resin composition, and a prepreg using the resin composition, a film with resin, a metal foil with resin, a metal-clad laminate, and a wiring board.

### BACKGROUND ART

In recent years, in various electronic devices, mounting technologies such as higher integration of semiconductor devices to be mounted, higher wiring density, and multi-layering have rapidly progressed along with an increase in the amount of information processed. Substrate materials for forming base materials of wiring boards used in various electronic devices are required to have a low dielectric constant and a low dielectric loss tangent to increase the transmission speed of signals and decrease the loss during signal transmission.

In particular, as typified by substrate-like printed wiring boards (SLP), the barrier between printed wiring boards and semiconductor package substrates is disappearing in recent years. Therefore, with the recent miniaturization and high performance of electronic devices and the remarkable improvement of information communication speed, any substrate is required to be compatible with high frequencies as well as exhibit excellent heat resistance and low thermal expansion properties.

In electronic substrate materials, polyphenylene ether compounds having a low dielectric constant and a low dielectric loss tangent are used in order to achieve low transmission loss at high frequencies.

For example, Patent Literature 1 reports that a cured product excellent in low dielectric properties and heat resistance is obtained from a thermosetting resin composition containing a terminal vinyl-benzyl-modified phenylene ether oligomer (polyphenylene ether compound) and a styrenic thermoplastic elastomer.

However, polyphenylene ether compounds have a relatively large coefficient of thermal expansion and also have problems in heat resistance although polyphenylene ether compounds are excellent in low dielectric properties.

Usually, electronic materials formed of curable resin compositions are considered to be stored and transported in the form of prepregs, films, and the like, but still have a problem of sticking of films and prepregs to each other when the resin composition is wound as a film or prepreg or in a case where prepregs and films are stacked so that the surfaces thereof overlap and packed and stored for a predetermined time.

The present invention is made in view of such circumstances, and an object thereof is to provide a resin composition affording a cured product that exhibits excellent low dielectric properties, heat resistance, and low thermal expansion properties and can exhibit suppressed surface tackiness (stickiness). Another object of the present invention is to provide a prepreg, a film with resin, a metal foil with resin, a metal-clad laminate, and a wiring board, which are obtained using the resin composition.

### CITATION LIST

### Patent Literature

Patent Literature 1: JP 4867217 B

### SUMMARY OF INVENTION

A resin composition according to an aspect of the present invention contains a hydrocarbon-based compound (A) represented by the following Formula (1):

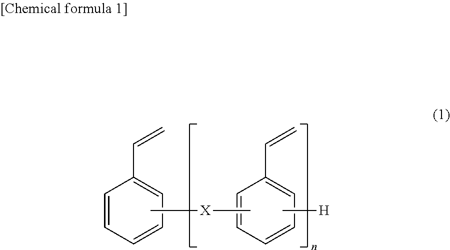

[In Formula (1), X represents a hydrocarbon group having 6 or more carbon atoms and containing at least one selected from an aromatic cyclic group or an aliphatic cyclic group, and n represents an integer from 1 to 10]; and
a styrenic polymer (B) that is solid at 25° C. and is different from the hydrocarbon-based compound (A).

### BRIEF DESCRIPTION OF DRAWINGS

FIG. 1 is a schematic sectional view illustrating the configuration of a prepreg according to an embodiment of the present invention.

FIG. 2 is a schematic sectional view illustrating the configuration of a metal-clad laminate according to an embodiment of the present invention.

FIG. 3 is a schematic sectional view illustrating the configuration of a wiring board according to an embodiment of the present invention.

FIG. 4 is a schematic sectional view illustrating the configuration of a metal foil with resin according to an embodiment of the present invention.

FIG. 5 is a schematic sectional view illustrating the configuration of a film with resin according to an embodiment of the present invention.

FIG. 6 illustrates a GPC chart of the compound obtained in Synthesis Example 1.

FIG. 7 illustrates a ¹H-NMR chart of the compound obtained in Synthesis Example 1.

FIG. 8 illustrates a GPC chart of the compound obtained in Synthesis Example 2.

FIG. 9 illustrates a ¹H-NMR chart of the compound obtained in Synthesis Example 2.

FIG. 10 is a schematic sectional view illustrating a test method for overhang evaluation.

### DESCRIPTION OF EMBODIMENTS

A resin composition according to an embodiment of the present invention (hereinafter also simply referred to as resin composition) contains a hydrocarbon-based compound (A) represented by Formula (1), and a styrenic polymer (B) that is solid at 25° C. and is different from the hydrocarbon-based compound (A).

By containing the hydrocarbon-based compound (A) and the styrenic polymer (B), it is possible to obtain a resin composition affording a cured product that exhibits excellent low dielectric properties, heat resistance, and low thermal expansion properties, has a high thermal decomposition temperature, and can exhibit suppressed surface tackiness (stickiness).

The cured product of the resin composition of the present embodiment has a high thermal decomposition temperature, which is considered to also afford excellent workability. It is considered that this is because less outgassing is generated from the resin composition during laser drilling. The workability referred to in the present embodiment is, for example, workability evaluated by the following overhang evaluation.

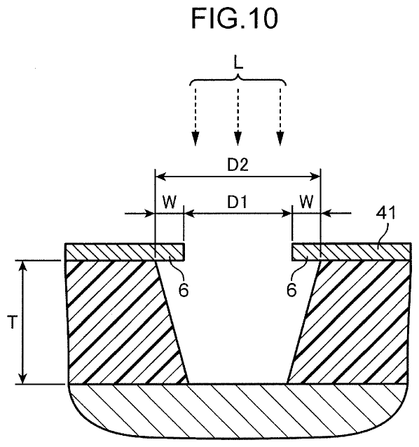

Overhang evaluation: Using a laser processing machine for substrate drilling, laser drilling is performed on an evaluation substrate 2 by a direct method using a CO₂ laser. Thus, a non-through hole penetrating a metal foil for outer layer 41 is formed. At this time, an inner diameter D1 of the through hole in the metal foil for outer layer 41 tends to be smaller than an inner diameter D2 of the non-through hole in the insulating layer, and a portion 6 protruding like a burr or eaves toward the center of the through hole in the metal foil for outer layer 41 is overhang (corresponding to W in FIG. 10). The length of overhang is measured for the non-through hole described above. It indicates that workability is greater as the length is shorter.

In other words, according to the present invention, it is possible to provide a resin composition affording a cured product that exhibits excellent low dielectric properties, heat resistance, and low thermal expansion properties and can exhibit suppressed surface tackiness (stickiness). By using the resin composition, it is possible to provide a prepreg, a film with resin, a metal foil with resin, a metal-clad laminate, and a wiring board, which exhibit properties such as low dielectric properties, high heat resistance, low thermal expansion properties, and a high thermal decomposition temperature.

Hereinafter, the respective components of the resin composition according to the present embodiment will be specifically described.

### <Hydrocarbon-Based Compound (A)>

The hydrocarbon-based compound (A) contained in the resin composition of the present embodiment is a compound represented by the following Formula (1).

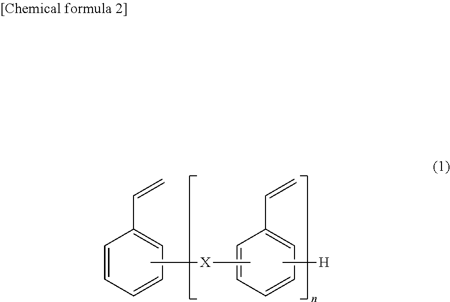

In Formula (1), X represents a hydrocarbon group having 6 or more carbon atoms and containing at least one selected from an aromatic cyclic group and an aliphatic cyclic group. n represents an integer from 1 to 10.

By containing such a hydrocarbon-based compound (A), it is considered that the resin composition of the present embodiment enables its cured product to attain excellent low dielectric properties and heat resistance, a high thermal decomposition temperature, and low thermal expansion properties.

The aromatic cyclic group is not particularly limited, but examples thereof include a phenylene group, a xylylene group, a naphthylene group, a tolylene group, and a biphenylene group.

The aliphatic cyclic group is not particularly limited, but examples thereof include a group containing an indane structure and a group containing a cycloolefin structure.

The number of carbon atoms is not particularly limited as long as it is 6 or more, but is more preferably 6 or more and 20 or less from the viewpoint of maintaining a high Tg.

In a preferred embodiment, the hydrocarbon-based compound of the present embodiment includes a hydrocarbon-based compound (A1) represented by the following Formula (2).

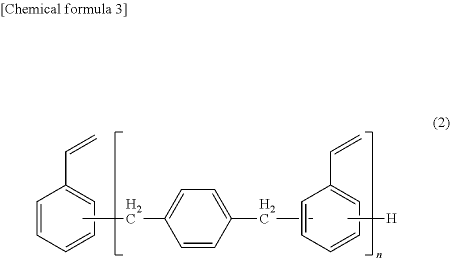

In Formula (2), n represents an integer from 1 to 10.

By containing such a hydrocarbon-based compound (A1), it is considered that the effects as described above can be attained more reliably.

### <Styrenic Polymer (B)>

The styrenic polymer (B) is a compound different from the hydrocarbon-based compound (A), and is not particularly limited as long as it is a styrenic polymer solid at 25° C. Examples of the styrenic polymer (B) include styrenic polymers that are solid at 25° C. and can be used as resins contained in resin compositions used for forming insulating layers of metal-clad laminates, wiring boards, and the like, and the like. The resin compositions used for forming insulating layers of metal-clad laminates, wiring boards and the like may be resin compositions used for forming resin layers of films with resin, metal foils with resin and the like, or may be a resin composition contained in prepregs. The styrenic polymer (B) is solid at 25° C., thus can suppress tackiness (stickiness), and affords excellent handleability when the resin composition of the present embodiment is formed into a semi-cured product or cured product. Regarding tackiness, it is possible to suppress the surface tackiness (stickiness) when the resin composition is formed into a film or prepreg, thus it is possible to suppress sticking of films or prepregs to each other when the films or prepregs are wound, and peeling off of (damage to) the resin of the films or prepregs caused by the sticking.

The styrenic polymer (B) is, for example, a polymer obtained by polymerizing a monomer including a styrenic monomer, and may be a styrenic copolymer. Examples of the styrenic copolymer (B) include a copolymer obtained by copolymerizing one or more styrenic monomers and one or more other monomers copolymerizable with the styrenic monomers. The styrenic copolymer (B) may be a random copolymer or a block copolymer as long as it has a structure derived from the styrenic monomer in the molecule. Examples of the block copolymer include a bipolymer of the structure (repeating unit) derived from the styrenic monomer and the other copolymerizable monomer (repeating unit) and a terpolymer of the structure (repeating unit) derived from the styrenic monomer, the other copolymerizable monomer (repeating unit), and the structure (repeating unit) derived from the styrenic monomer.

The styrenic polymer (B) may be a hydrogenated styrenic copolymer obtained by hydrogenating the styrenic copolymer. By containing the hydrogenated styrenic copolymer, it is considered to have an advantage of preventing deterioration in dielectric properties due to oxidative degradation.

The styrenic monomer is not particularly limited, but examples thereof include styrene, a styrene derivative, one in which some hydrogen atoms of the benzene ring in styrene are substituted with an alkyl group, one in which some hydrogen atoms of the vinyl group in styrene are substituted with an alkyl group, vinyltoluene, α-methylstyrene, butylstyrene, dimethylstyrene, and isopropenyltoluene. As the styrenic monomer, these may be used singly or in combination of two or more kinds thereof. The other copolymerizable monomer is not particularly limited, but examples thereof include olefins such as α-pinene, β-pinene, and dipentene, unconjugated dienes such as 1,4-hexadiene and 3-methyl-1,4-hexadiene, and conjugated dienes such as 1,3-butadiene and 2-methyl-1,3-butadiene (isoprene). As the other copolymerizable monomer, these may be used singly or in combination of two or more kinds thereof.

In the present embodiment, as the styrenic polymer (B) is not particularly limited, and conventionally known ones can be widely used, but examples thereof include a polymer having a structural unit represented by the following Formula (3) (a structure derived from the styrenic monomer) in the molecule.

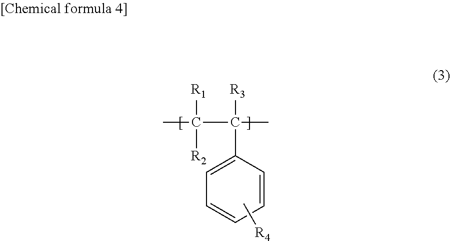

In Formula (3), R₁ to R₃ each independently represent a hydrogen atom or an alkyl group, and R₄ represents any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic polymer (B) preferably contains at least one structural unit represented by Formula (3), and may contain two or more different structural units in combination. The styrenic polymer may contain a structure in which the structural unit represented by Formula (3) is repeated.

The styrenic polymer (B) may have at least one among the structural units represented by the following Formulas (4), (5) and (6) as a structural unit derived from another monomer copolymerizable with the styrenic monomer in addition to the structural unit represented by Formula (3).

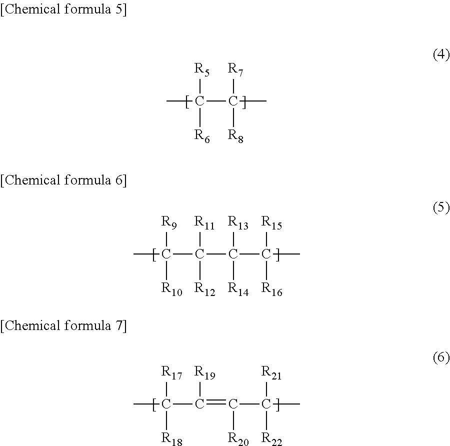

In Formula (4), Formula (5), and Formula (6), R₅ to R₂₂ each independently represent any group selected from the group consisting of a hydrogen atom, an alkyl group, an alkenyl group, and an isopropenyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group. The alkenyl group is preferably an alkenyl group having 1 to 10 carbon atoms.

The styrenic polymer (B) preferably contains at least one among the structural units represented by Formula (4), Formula (5), and Formula (6), and may contain two or more different structural units among these in combination. The styrenic polymer (B) may have at least one among structures in which the structural units represented by Formula (4), Formula (5), and Formula (6) are each repeated.

More specific examples of the structural unit represented by Formula (3) include structural units represented by the following Formulas (7) to (9). The structural unit represented by Formula (3) may be structures in which structural units represented by the following Formulas (7) to (9) are each repeated, and the like. The structural unit represented by Formula (3) may be one structural unit among these or a combination of two or more different structural units.

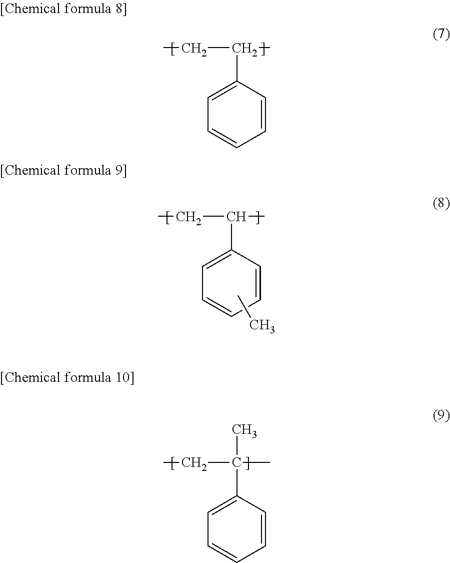

More specific examples of the structural unit represented by Formula (4) include structural units represented by the following Formulas (10) to (16). The structural unit represented by Formula (4) may be structures in which structural units represented by the following Formulas (10) to (16) are each repeated, and the like. The structural unit represented by Formula (4) may be one structural unit among these or a combination of two or more different structural units.

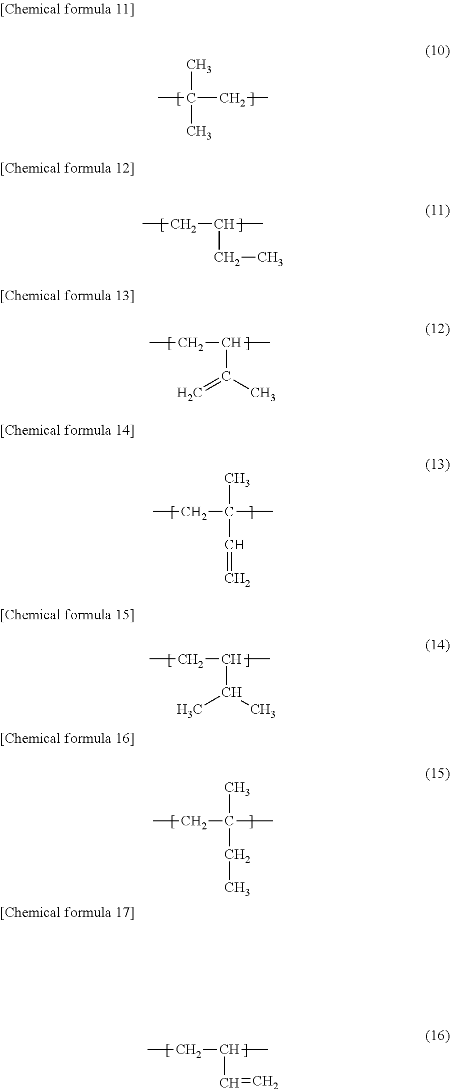

More specific examples of the structural unit represented by Formula (5) include structural units represented by the following Formulas (17) and (18). The structural unit represented by Formula (5) may be structures in which structural units represented by the following Formulas (17) and (18) are each repeated, and the like. The structural unit represented by Formula (5) may be one structural unit among these or a combination of two or more different structural units.

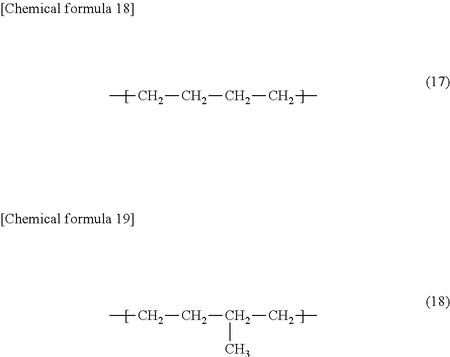

More specific examples of the structural unit represented by Formula (6) include structural units represented by the following Formulas (19) and (20). The structural unit represented by Formula (6) may be structures in which structural units represented by the following Formulas (19) and (20) are each repeated, and the like. The structural unit represented by Formula (6) may be one structural unit among these or a combination of two or more different structural units.

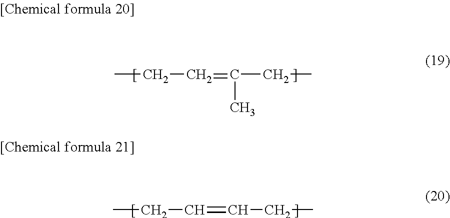

Preferred examples of the styrenic copolymer (B) include polymers or copolymers obtained by polymerizing or copolymerizing one or more styrenic monomers such as styrene, vinyltoluene, α-methylstyrene, isopropenyltoluene, divinylbenzene, or allylstyrene.

More specific examples of the styrenic copolymer (B) include a methylstyrene (ethylene/butylene) methylstyrene block copolymer, a methylstyrene (ethylene-ethylene/propylene) methylstyrene block copolymer, a styrene isoprene block copolymer, a styrene isoprene styrene block copolymer, a styrene (ethylene/butylene) styrene block copolymer, a styrene (ethylene-ethylene/propylene) styrene block copolymer, a styrene butadiene styrene block copolymer, a styrene (butadiene/butylene) styrene block copolymer, and a styrene isobutylene styrene block copolymer.

Examples of the hydrogenated styrenic block copolymer include hydrogenated products of the styrenic block copolymers. More specific examples of the hydrogenated styrenic block copolymer include a hydrogenated methylstyrene (ethylene/butylene) methylstyrene block copolymer, a hydrogenated methylstyrene (ethylene-ethylene/propylene) methylstyrene block copolymer, a hydrogenated styrene isoprene block copolymer, a hydrogenated styrene isoprene styrene block copolymer, a hydrogenated styrene (ethylene/butylene) styrene block copolymer, and a hydrogenated styrene (ethylene-ethylene/propylene) styrene block copolymer.

As the styrenic polymer (B), the styrenic polymers exemplified above may be used singly or in combination of two or more kinds thereof.

The weight average molecular weight of the styrenic polymer (B) is preferably 1,000 to 300,000, more preferably 1,200 to 200,000. When the molecular weight is too low, the glass transition temperature or heat resistance of the cured product of the resin composition tends to decrease. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

As the styrenic polymer (B), a commercially available product can be used, and for example, V9827, V9461, 1020, 2002, 2004F, 2005, 2006, 2063, 2104, 4033, 4044, 4055, 4077, 4099, 8004, 8006, 8007L, HG252, 5125, 5127, 7125F, and 7311F manufactured by KURARAY CO., LTD.; FTR2140 and FTR6125 manufactured by Mitsui Chemicals, Inc.; H1221, H1062, H1521, H1052, H1053, H1041, H1051, H1517, H1043, N504, H1272, M1943, M1911, M1913, MP10, P1083, P1500, P5051, and P2000 manufactured by Asahi Kasei Corporation; DYNARON series 1320P, 1321P, 2324P, 4600P, 6200P, 6201 B, 8600P, 8300P, 8903P, and 9901P manufactured by JSR Corporation; and SIBSTAR series 062M, 062T, 072T, 073T, 102T, and 103T manufactured by KANEKA CORPORATION may be used.

### <Reactive Compound (C)>

The resin composition according to the present embodiment may contain a reactive compound (C) that reacts with at least one of the hydrocarbon-based compound (A) and the styrenic polymer (B), if necessary, as long as the effects of the present invention are not impaired. By containing such a reactive compound (C), it is considered that close contact properties (for example, close contact properties to metal foil) and low thermal expansion properties can be further imparted to the resin composition.

The reactive compound refers to a compound that reacts with at least one of the hydrocarbon-based compound (A) and the styrenic polymer (B) and contributes to curing of the resin composition. Examples of the reactive compound (C) include a maleimide compound, an epoxy compound, a methacrylate compound, an acrylate compound, a vinyl compound that is liquid at 25° C., a cyanate ester compound, an active ester compound, an allyl compound, a benzoxazine compound, a phenol compound, and a polyphenylene ether compound.

The maleimide compound is not particularly limited as long as it is a maleimide compound having a maleimide group in the molecule, and examples thereof include a maleimide compound having one or more maleimide groups in the molecule and a modified maleimide compound.

More specific examples of the malcimide compound (D) include phenylmaleimide compounds such as 4,4′-diphenylmethanebismaleimide, polyphenylmethane maleimide, m-phenylenebismaleimide, bisphenol A diphenyl ether bismaleimide, 3,3′-dimethyl-5,5′-diethyl-4,4′-diphenylmethanebismaleimide, 4-methyl-1,3-phenylenebismalcimide, and a biphenylaralkyl-type polymaleimide compound, and a N-alkylbismaleimide compound having an aliphatic skeleton.

Examples of the modified maleimide compound include a modified maleimide compound in which a part of the molecule is modified with an amine compound and a modified malcimide compound in which a part of the molecule is modified with a silicone compound. As a maleimide compound different from the maleimide compound, a commercially available product can also be used, and for example, MIR-3000-70MT and MIR-5000 manufactured by Nippon Kayaku Co., Ltd., BMI-4000, BMI-5100, BMI-2300, and BMI-TMH manufactured by Daiwa Kasei Industry Co., Ltd., and BMI-689, BMI-1500, BMI-3000J and BMI-5000 manufactured by Designer Molecules Inc. may be used.

The epoxy compound is a compound having an epoxy group in the molecule, and specific examples thereof include a bixylenol-type epoxy compound, a bisphenol A-type epoxy compound, a bisphenol F-type epoxy compound, a bisphenol S-type epoxy compound, a bisphenol AF-type epoxy compound, a dicyclopentadiene-type epoxy compound, a trisphenol-type epoxy compound, a naphthol novolac-type epoxy compound, a phenol novolac-type epoxy compound, a tert-butyl-catechol-type epoxy compound, a naphthalene-type epoxy compound, a naphthol-type epoxy compound, an anthracene-type epoxy compound, a glycidylamine-type epoxy compound, a glycidyl ester-type epoxy compound, a cresol novolac-type epoxy compound, a biphenyl-type epoxy compound, a linear aliphatic epoxy compound, an epoxy compound having a butadiene structure, an alicyclic epoxy compound, a heterocyclic epoxy compound, a spiro ring-containing epoxy compound, a cyclohexane-type epoxy compound, a cyclohexanedimethanol-type epoxy compound, a naphthylene ether-type epoxy compound, a trimethylol-type epoxy compound, and a tetraphenylethane-type epoxy compound. The epoxy compound also includes an epoxy resin, which is a polymer of each of the epoxy compounds.

The methacrylate compound is a compound having a methacryloyl group in the molecule, and examples thereof include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include dimethacrylate compounds such as tricyclodecanedimethanol dimethacrylate (DCP).

The acrylate compound is a compound having an acryloyl group in the molecule, and examples thereof include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include diacrylate compounds such as tricyclodecanedimethanol diacrylate.

The vinyl compound that is liquid at 25° C. is a vinyl compound different from the component (B) and is a compound that is liquid at 25° C. and has a vinyl group in the molecule, and examples thereof include a monofunctional vinyl compound (monovinyl compound) having one vinyl group in the molecule and a polyfunctional vinyl compound having two or more vinyl groups in the molecule. Examples of the polyfunctional vinyl compound include divinylbenzene, curable polybutadiene having a carbon-carbon unsaturated double bond in the molecule, and a curable butadiene-styrene copolymer having a carbon-carbon unsaturated double bond in the molecule.

The cyanate ester compound is a compound having a cyanato group in the molecule, and examples thereof include a phenol novolac-type cyanate ester compound, a naphthol aralkyl-type cyanate ester compound, a biphenyl aralkyl-type cyanate ester compound, a naphthylene ether-type cyanate ester compound, a xylene resin-type cyanate ester compound, and an adamantane skeleton-type cyanate ester compound.

The active ester compound is a compound having an ester group exhibiting high reaction activity in the molecule, and examples thereof include a benzenecarboxylic acid active ester, a benzenedicarboxylic acid active ester, a benzenetricarboxylic acid active ester, a benzenetetracarboxylic acid active ester, a naphthalenecarboxylic acid active ester, a naphthalenedicarboxylic acid active ester, a naphthalenetricarboxylic acid active ester, a naphthalenetetracarboxylic acid active ester, a fluorenecarboxylic acid active ester, a fluorenedicarboxylic acid active ester, a fluorenetricarboxylic acid active ester, and a fluorenetetracarboxylic acid active ester.

The allyl compound is a compound having an allyl group in the molecule, and examples thereof include a triallyl isocyanurate compound such as triallyl isocyanurate (TAIC), a diallyl bisphenol compound, and diallyl phthalate (DAP).

As the benzoxazine compound, for example, a benzoxazine compound represented by the following General Formula (C-1) can be used.

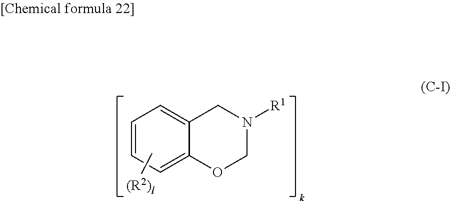

In Formula (C-1), R¹ represents a k-valent group, and each R² independently represents a halogen atom, an alkyl group, or an aryl group. k represents an integer from 2 to 4 and 1 represents an integer from 0 to 4.

Commercially available products include “JBZ-OP100D” and “ODA-BOZ” manufactured by JFE Chemical Corporation; “P-d”, “F-a” and “ALP-d” manufactured by SHIKOKU CHEMICALS CORPORATION, and “HFB2006M” manufactured by Showa Highpolymer Co., Ltd. and the like.

As the phenol compound, a compound containing a hydroxy group bonded to an aromatic ring in the molecule can be used, and examples thereof include a bisphenol A-type phenol compound, a bisphenol E-type phenol compound, a bisphenol F-type phenol compound, a bisphenol S-type phenol compound, a phenol novolac compound, a bisphenol A novolac-type phenol compound, a glycidyl ester-type phenol compound, an aralkyl novolac-type phenol compound, a biphenylaralkyl-type phenol compound, a cresol novolac-type phenol compound, a polyfunctional phenol compound, a naphthol compound, a naphthol novolac compound, a polyfunctional naphthol compound, an anthracene-type phenol compound, a naphthalene skeleton-modified novolac-type phenol compound, a phenol aralkyl-type phenol compound, a naphtholaralkyl-type phenol compound, a dicyclopentadiene-type phenol compound, a biphenyl-type phenol compound, an alicyclic phenol compound, a polyol-type phenol resin, a phosphorus-containing phenol compound, a polymerizable unsaturated hydrocarbon group-containing phenol compound, and a hydroxyl group-containing silicone compound.

The polyphenylene ether compound can be synthesized by a known method, or a commercially available product can be used. Examples of the commercially available product include “OPE-2st 1200” and “OPE-2st 2200” manufactured by Mitsubishi Gas Chemical Company Inc., and “SA9000”, “SA90”, “SA120” and “Noryl640” manufactured by SABIC Innovative Plastics.

As the reactive compound (C), the compounds mentioned above may be used singly or in combination of two or more kinds thereof.

### (Content)

In the resin composition of the present embodiment, the content of the hydrocarbon-based compound (A) is preferably 20 to 80 parts by mass with respect to 100 parts by mass of the total mass of the hydrocarbon-based compound (A) and the styrenic polymer (B). When the content is in such a range, it is considered that the effects of the present invention as described above can be attained more reliably. A more preferable range of the content is 20 parts by mass or more and 50 parts by mass or less.

In a case where the resin composition of the present embodiment contains the reactive compound (C), the content of the styrenic polymer (B) is preferably 5 to 80 parts by mass, more preferably 5 to 50 parts by mass with respect to 100 parts by mass of the sum of the hydrocarbon-based compound (A), the styrenic polymer (B), and the reactive compound (C).

In that case, the content of the reactive compound (C) is preferably 1 to 40 parts by mass, more preferably 5 to 30 parts by mass with respect to 100 parts by mass of the sum of the hydrocarbon-based compound (A), the styrenic polymer (B), and the reactive compound (C).

### (Inorganic Filler)

The resin composition according to the present embodiment may further contain an inorganic filler. The inorganic filler is not particularly limited and includes those added to enhance the heat resistance and flame retardancy of the cured product of a resin composition. By containing an inorganic filler, it is considered that heat resistance, flame retardancy and the like can be further enhanced as well as the coefficient of thermal expansion can be kept lower (achievement of even lower thermal expansion properties).

Specific examples of the inorganic filler that can be used in the present embodiment include metal oxides such as silica, alumina, titanium oxide, magnesium oxide, and mica, metal hydroxides such as magnesium hydroxide and aluminum hydroxide, talc, aluminum borate, barium sulfate, aluminum nitride, boron nitride, barium titanate, strontium titanate, calcium titanate, aluminum titanate, barium zirconate titanate, barium zirconate, calcium zirconate, zirconium phosphate, zirconium tungstate phosphate, magnesium carbonate such as anhydrous magnesium carbonate, calcium carbonate, and boehmite-treated products thereof. Among these, silica, metal hydroxides such as magnesium hydroxide and aluminum hydroxide, aluminum oxide, boron nitride, and barium titanate, strontium titanate and the like are preferable, and silica is more preferable. The silica is not particularly limited, and examples thereof include crushed silica, spherical silica, and silica particles.

These inorganic fillers may be used singly or in combination of two or more kinds thereof. An inorganic filler as described above may be used as it is, but one subjected to a surface treatment with an epoxysilane-type, vinylsilane-type, methaerylsilane-type, phenylaminosilane-type, or aminosilane-type silane coupling agent may be used. The silane coupling agent can be used by being added to the filler by an integral blend method instead of the method of treating the surface of the filler with the silane coupling agent in advance.

In a case where the resin composition of the present embodiment contains an inorganic filler, the content of the inorganic filler is preferably 10 to 300 parts by mass, more preferably 40 to 250 parts by mass with respect to 100 parts by mass of the total mass of the maleimide compound (A) and the hydrocarbon-based compound (B).

### (Flame Retardant)

The resin composition according to the present embodiment may further contain a flame retardant. The flame retardancy of a cured product of the resin composition can be further enhanced by containing a flame retardant.

The flame retardant that can be used in the present embodiment is not particularly limited. Specifically, in the field in which halogen-based flame retardants such as bromine-based flame retardants are used, for example, ethylenedipentabromobenzene, ethylenebistetrabromoimide, decabromodiphenyloxide, and tetradecabromodiphenoxybenzene which have a melting point of 300° C. or more are preferable. It is considered that the elimination of halogen at a high temperature and the decrease in heat resistance can be suppressed by the use of a halogen-based flame retardant. There is a case where a flame retardant containing phosphorus (phosphorus-based flame retardant) is used in fields required to be halogen-free. The phosphorus-based flame retardant is not particularly limited, and examples thereof include an HCA-based flame retardant, a phosphate ester-based flame retardant, a phosphazene-based flame retardant, a bis(diphenylphosphine oxide)-based flame retardant, and a phosphinate-based flame retardant. Specific examples of the HCA-based flame retardant include 9,10-dihydro-9-oxa-10-phosphaphenanthren-10-yl-10-oxide, 10-(2,5-dihydroxyphenyl)-9,10-dihydro-9-oxa-10-phosphaphenanthrene-10-oxide, or compounds obtained by reacting these in advance. Specific examples of the phosphate ester-based flame retardant include a condensed phosphate ester such as dixylenyl phosphate. Specific examples of the phosphazene-based flame retardant include phenoxyphosphazene. Specific examples of the bis(diphenylphosphine oxide)-based flame retardant include xylylenebis(diphenylphosphine oxide). Specific examples of the phosphinate-based flame retardant include metal phosphinates such as an aluminum dialkyl phosphinate. As the flame retardant, the respective flame retardants exemplified may be used singly or in combination of two or more kinds thereof.

In a case where the resin composition of the present embodiment contains a flame retardant, the content of the flame retardant is preferably 3 to 50 parts by mass, more preferably 5 to 40 parts by mass with respect to 100 parts by mass of the total mass of the resin composition except for the inorganic filler.

### Other Components

The resin composition according to the present embodiment may contain components (other components) other than the components described above if necessary as long as the effects of the present invention are not impaired. As the other components contained in the resin composition according to the present embodiment, for example, additives such as catalysts including a reaction initiator and a reaction accelerator, a silane coupling agent, a polymerization inhibitor, a polymerization retardant, an auxiliary flame retardant, an antifoaming agent, a leveling agent, an antioxidant, a heat stabilizer, an antistatic agent, an ultraviolet absorber, a dye or a pigment, a dispersant, and a lubricant may be further contained.

The resin composition according to the present embodiment may contain a reaction initiator (catalyst) and a reaction accelerator as described above. The reaction initiator and reaction accelerator are not particularly limited as long as they can promote the curing reaction of the resin composition. Specifically, examples thereof include metal oxides, azo compounds, peroxides, imidazole compounds, phosphorus-based curing accelerators, and amine-based curing accelerators.

Specific examples of metal oxides include zinc octylate, tin octylate, zinc naphthenate, cobalt naphthenate, tin stearate, and zinc stearate.

Examples of peroxides include α,α′-di(t-butylperoxy)diisopropylbenzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile.

Specific examples of azo compounds include 2,2′-azobis(2,4,4-trimethylpentane), 2,2′-azobis(N-butyl-2-methylpropionamide), and 2,2′-azobis(2-methylbutyronitrile).

Among these, α,α′-di(t-butylperoxy)diisopropylbenzene is preferably used as a preferable reaction initiator. α,α′-Di(t-butylperoxy)diisopropylbenzene exhibits low volatility, thus does not volatilize at the time of drying and storage, and exhibits favorable stability. α,α′-Di(t-butylperoxy)diisopropylbenzene has a relatively high reaction initiation temperature and thus can suppress the promotion of the curing reaction at the time point at which curing is not required, for example, at the time of prepreg drying. By suppressing the curing reaction, it is possible to suppress a decrease in storage stability of the resin composition.

Examples of phosphorus-based curing accelerators include triphenylphosphine, phosphonium borate compounds, tetraphenylphosphonium tetraphenylborate, n-butylphosphonium tetraphenylborate, tetrabutylphosphonium decanoate, (4-methylphenyl)triphenylphosphonium thiocyanate, tetraphenylphosphonium thiocyanate, and butyltriphenylphosphonium thiocyanate.

Examples of amine-based curing accelerators include trialkylamines such as triethylamine and tributylamine, 4-dimethylaminopyridine (DMAP), benzyldimethylamine, 2,4,6-tris(dimethylaminomethyl)phenol, and 1,8-diazabicyclo(5,4,0)-undecene.

Examples of imidazole-based compounds include imidazole compounds such as 2-methylimidazole, 2-undecylimidazole, 2-heptadecylimidazole, 1,2-dimethylimidazole, 2-ethyl-4-methylimidazole, 1,2-dimethylimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, 1-cyanoethyl-2-undecylimidazole, 1-cyanoethyl-2-ethyl-4-methylimidazole, 1-cyanoethyl-2-phenylimidazole, 1-cyanoethyl-2-undecylimidazolium trimellitate, 1-cyanoethyl-2-phenylimidazolium trimellitate, 2,4-diamino-6-[2′-methylimidazolyl-(1′)]-ethyl-s-triazine, 2,4-diamino-6-[2′-undecylimidazolyl-(1′)]-ethyl-s-triazine, 2,4-diamino-6-[2′-ethyl-4′-methylimidazolyl-(1′)]-ethyl-s-triazine, 2,4-diamino-6-[2′-methylimidazolyl-(1′)]-ethyl-s-triazine isocyanuric acid adduct, 2-phenylimidazole isocyanuric acid adduct, 2-phenyl-4,5-dihydroxymethylimidazole, 2-phenyl-4-methyl-5-hydroxymethylimidazole, 2,3-dihydro-1H-pyrrolo[1,2-a]benzimidazole, 1-dodecyl-2-methyl-3-benzylimidazolium chloride, 2-methylimidazoline, and 2-phenylimidazoline.

The reaction initiators as described above may be used singly or in combination of two or more kinds thereof.

In a case where the resin composition of the present embodiment contains the reaction initiator, the content of the reaction initiator is not particularly limited, but is, for example, preferably 0.01 to 5.0 parts by mass, more preferably 0.01 to 3 parts by mass, still more preferably 0.05 to 3.0 parts by mass with respect to 100 parts by mass of the sum of the maleimide compound (A) and the hydrocarbon-based compound (B) (and the reactive compound (C) in a case of containing the reactive compound (C)).

(Prepreg, Film with Resin, Metal-Clad Laminate, Wiring Board, and Metal Foil with Resin)

Next, a prepreg for wiring board, a metal-clad laminate, a wiring board, and a metal foil with resin obtained using the resin composition of the present embodiment will be described. The respective symbols in the drawings indicate the following: 1 prepreg, 2 resin composition or semi-cured product of resin composition, 3 fibrous base material, 11 metal-clad laminate, 12 insulating layer, 13 metal foil, 14 wiring, 21 wiring board, 31 metal foil with resin, 32, 42 resin layer, 41 film with resin, and 43 support film.

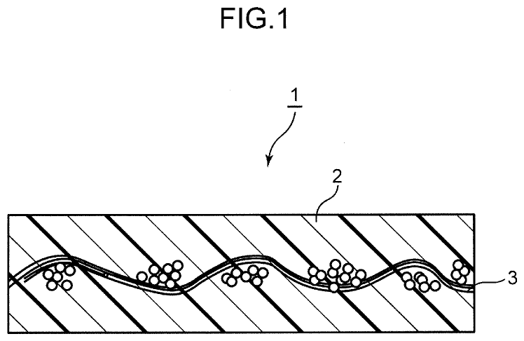

FIG. 1 is a schematic sectional view illustrating an example of a prepreg 1 according to an embodiment of the present invention.

As illustrated in FIG. 1, the prepreg 1 according to the present embodiment includes the resin composition or a semi-cured product 2 of the resin composition and a fibrous base material 3. Examples of the prepreg 1 include those in which the fibrous base material 3 is present in the resin composition or a semi-cured product 2 thereof. In other words, the prepreg 1 includes the resin composition or semi-cured product thereof; and the fibrous base material 3 present in the resin composition or semi-cured product 2 thereof.

In the present embodiment, the “semi-cured product” is one in a state in which the resin composition is partly cured so as to be further cured. In other words, the semi-cured product is the resin composition in a semi-cured state (B-staged). For example, when a resin composition is heated, the viscosity of the resin composition first gradually decreases, then curing starts, and the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the resin composition in B stage) and a fibrous base material, or may be a prepreg including the resin composition before curing (the resin composition in A stage) and a fibrous base material. Specific examples of the prepreg include those in which a fibrous base material is present in the resin composition. The resin composition or semi-cured product thereof may be one obtained by heating and drying the resin composition.

When the prepreg and the metal foil with resin, metal-clad laminate and the like to be described later are fabricated, the resin composition according to the present embodiment is often prepared in the form of a varnish and used as a resin varnish. Such a resin varnish is prepared, for example, as follows.

First, the respective components that can be dissolved in an organic solvent, such as a resin component and a reaction initiator, are put into an organic solvent and dissolved. At this time, heating may be performed if necessary. Thereafter, an inorganic filler and the like, which are components that do not dissolve in an organic solvent, are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the hydrocarbon-based compound (A), the styrenic polymer (B), and if necessary, the reactive compound (C) and the like and does not inhibit the curing reaction. Specific examples thereof include toluene, methyl ethyl ketone, cyclohexanone, cyclopentanone, methylcyclohexane, dimethylformamide, and propylene glycol monomethyl ether acetate. These may be used singly or two or more kinds thereof may be used concurrently.

Examples of the method for fabricating the prepreg 1 of the present embodiment using the varnish-like resin composition of the present embodiment include a method in which the fibrous base material 3 is impregnated with the resin composition 2 in the form of a resin varnish and then drying is performed.

Specific examples of the fibrous base material used in fabrication of the prepreg include glass cloth, aramid cloth, polyester cloth, LCP (liquid crystal polymer) nonwoven fabric, glass nonwoven fabric, aramid nonwoven fabric, polyester nonwoven fabric, pulp paper, and linter paper. When glass cloth is used, a laminate exhibiting excellent mechanical strength is obtained, and glass cloth subjected to flattening is particularly preferable. The glass cloth used in the present embodiment is not particularly limited, but examples thereof include glass cloth with low dielectric constant such as E glass, S glass, NE glass, Q glass, and L glass. Specifically, the flattening can be carried out, for example, by continuously pressing the glass cloth with press rolls at an appropriate pressure to flatten the yarn. As for the thickness of the fibrous base material, for example, a fibrous base material having a thickness of 0.01 to 0.3 mm can be generally used.

Impregnation of the fibrous base material 3 with the resin varnish (resin composition 2) is performed by dipping, coating, or the like. This impregnation can be repeated multiple times if necessary. At this time, it is also possible to repeat impregnation using a plurality of resin varnishes having different compositions and concentrations, and adjust the composition (content ratio) and resin amount to the finally desired values.

The fibrous base material 3 impregnated with the resin varnish (resin composition 2) is heated under desired heating conditions, for example, at 80° C. or more and 180° C. or less for 1 minute or more and 10 minutes or less. By heating, the solvent is volatilized from the varnish and the solvent is diminished or removed to obtain the prepreg 1 before curing (in A stage) or in a semi-cured state (B stage).

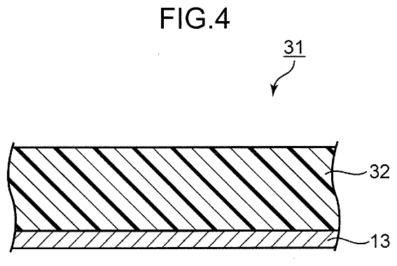

As illustrated in FIG. 4, a metal foil with resin 31 of the present embodiment has a configuration in which a resin layer 32 containing the resin composition described above or a semi-cured product of the resin composition; and a metal foil 13 are laminated. In other words, the metal foil with resin of the present embodiment may be a metal foil with resin including a resin layer containing the resin composition before curing (the resin composition in A stage) and a metal foil, or may be a metal foil with resin including a resin layer containing a semi-cured product of the resin composition (the resin composition in B stage) and a metal foil.

Examples of the method for fabricating such a metal foil with resin 31 include a method in which a resin composition in the form of a resin varnish as described above is applied to the surface of the metal foil 13 such as a copper foil and then dried. Examples of the coating method include a bar coater, a comma coater, a die coater, a roll coater, and a gravure coater.

As the metal foil 13, metal foils used in metal-clad laminates, wiring boards and the like can be used without limitation, and examples thereof include copper foil and aluminum foil.

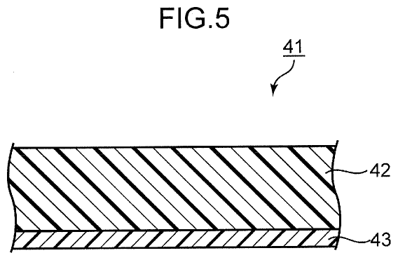

As illustrated in FIG. 5, a film with resin 41 of the present embodiment has a configuration in which a resin layer 42 containing the resin composition described above or a semi-cured product of the resin composition; and a film supporting base material 43 are laminated. In other words, the film with resin of the present embodiment may be a film with resin including the resin composition before curing (the resin composition in A stage); and a film supporting base material, or a film with resin including a semi-cured product of the resin composition (the resin composition in B stage); and a film supporting base material.

As the method for fabricating such a film with resin 41, for example, a resin composition in the form of a resin varnish as described above is applied to the surface of the film supporting base material 43, and then the solvent is volatilized from the varnish and diminished or removed, whereby a film with resin before curing (A stage) or in a semi-cured state (B stage) can be obtained.

Examples of the film supporting base material include electrical insulating films such as a polyimide film, a PET (polyethylene terephthalate) film, a polyethylene naphthalate film, a polyester film, a poly(parabanic acid) film, a polyether ether ketone film, a polyphenylene sulfide film, an aramid film, a polycarbonate film, and a polyarylate film.

In the film with resin and metal foil with resin of the present embodiment, the resin composition or semi-cured product thereof may be one obtained by drying or heating and drying the resin composition as in the prepreg described above.

The thickness and the like of the metal foil 13 and the film supporting base material 43 can be appropriately set depending on the desired purpose. For example, as the metal foil 13, a metal foil having a thickness of about 1 to 70 μm can be used. In a case where the thickness of metal foil is, for example, 10 μm or less, the metal foil may be a carrier-attached copper foil including a release layer and a carrier in order to improve handleability. The application of the resin varnish to the metal foil 13 and the film supporting base material 43 is performed by coating or the like, and this can be repeated multiple times if necessary. At this time, it is also possible to repeat coating using a plurality of resin varnishes having different compositions and concentrations, and adjust the composition (content ratio) and resin amount to the finally desired values.

Drying or heating and drying conditions in the fabrication method of the metal foil with resin 31 and film with resin 41 are not particularly limited, but a resin composition in the form of a resin varnish is applied to the metal foil 13 and film supporting base material 43, and then heating is performed under desired heating conditions, for example, at 50° C. to 180° C. for about 0.1 to 10 minutes to volatilize the solvent from the varnish and diminish or remove the solvent, whereby the metal foil with resin 31 and film with resin 41 before curing (A stage) or in a semi-cured state (B stage) are obtained.

The metal foil with resin 31 and film with resin 41 may include a cover film and the like, if necessary. By including a cover film, it is possible to prevent foreign matter from entering. The cover film is not particularly limited as long as it can be peeled off without damaging the form of the resin composition, and for example, a polyolefin film, a polyester film, a TPX film, films formed by providing a mold releasing agent layer on these films, and paper obtained by laminating these films on a paper base material can be used.

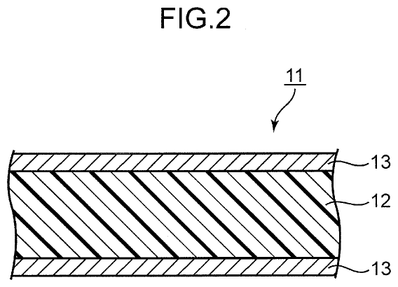

As illustrated in FIG. 2, a metal-clad laminate 11 of the present embodiment includes an insulating layer 12 containing a cured product of the resin composition described above or a cured product of the prepreg described above; and a metal foil 13. As the metal foil 13 used in the metal-clad laminate 11, a metal foil similar to the metal foil 13 described above can be used.

The metal-clad laminate 11 of the present embodiment can also be fabricated using the metal foil with resin 31 or film with resin 41 described above.

As the method for fabricating a metal-clad laminate using the prepreg 1, metal foil with resin 31, or film with resin 41 obtained in the manner described above, one or a plurality of prepregs 1, metal foils with resin 31, or films with resin 41 are superimposed on one another, and the metal foils 13 such as copper foil are further superimposed on both upper and lower sides or on one side, and this is laminated and integrated by heating and pressing, whereby a double-sided metal-clad or single-sided metal-clad laminate can be fabricated. The heating and pressing conditions can be appropriately set depending on the thickness of the laminate to be fabricated, the kind of the resin composition, and the like, but for example, the temperature may be set to 170° C. to 230° C., the pressure may be set to 1.5 to 5.0 MPa, and the time may be set to 60 to 150 minutes.

The metal-clad laminate 11 may be fabricated by forming a film-like resin composition on the metal foil 13 without using the prepreg 1 or the like and performing heating and pressing.

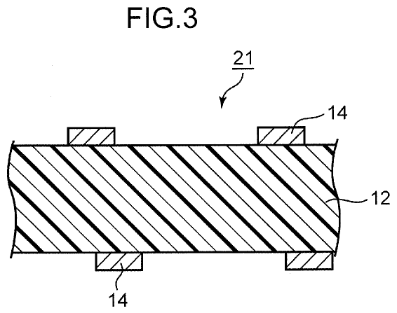

As illustrated in FIG. 3, a wiring board 21 of the present embodiment includes wiring 14 and an insulating layer 12 containing a cured product of the resin composition described above or a cured product of the prepreg described above.

The resin composition of the present embodiment is suitably used as a material for an insulating layer of a wiring board. As the method for fabricating the wiring board 21, for example, the metal foil 13 on the surface of the metal-clad laminate 11 obtained above is etched to form a circuit (wiring), whereby the wiring board 21 having a conductor pattern (wiring 14) provided as a circuit on the surface of a laminate can be obtained. Examples of the circuit forming method include circuit formation by a semi additive process (SAP) or a modified semi additive process (MSAP) in addition to the method described above.

The prepreg, film with resin, and metal foil with resin obtained using the resin composition of the present embodiment are extremely useful in industrial applications since the cured products thereof exhibit excellent low dielectric properties, heat resistance, and low thermal expansion properties, has a high thermal decomposition temperature, and can exhibit suppressed surface tackiness (stickiness), which affords excellent handleability. The metal-clad laminate and wiring board obtained by curing these have the advantages of excellent low dielectric properties, heat resistance, and low thermal expansion properties as well as excellent workability.

Hereinafter, the present invention will be described more specifically with reference to Examples, but the scope of the present invention is not limited thereto.

### EXAMPLES

First, the components to be used in the preparation of resin compositions in the following examples will be described.

### (Hydrocarbon-Based Compound (A))

### Production of Hydrocarbon-Based Compound 1

First, the weight average molecular weight (Mw) and number average molecular weight (Mn) used in the production of hydrocarbon-based compound 1 below are values determined by the following analysis method.

### (Analysis Method)

The molecular weights were calculated in terms of polystyrene using a polystyrene standard solution.

GPC: DGU-20A3R, LC-20AD, SIL-20AHT, RID-20A, SPD-20A, CTO-2, CBM-20A (all manufactured by Shimadzu Corporation)

Column: Shodex KF-603, KF-602x2, KF-601x2)

Coupled eluent: Tetrahydrofuran

Flow velocity: 0.5 ml/min.

Column temperature: 40° C.

Detection: RI (differential refraction detector)

### Synthesis Example 1

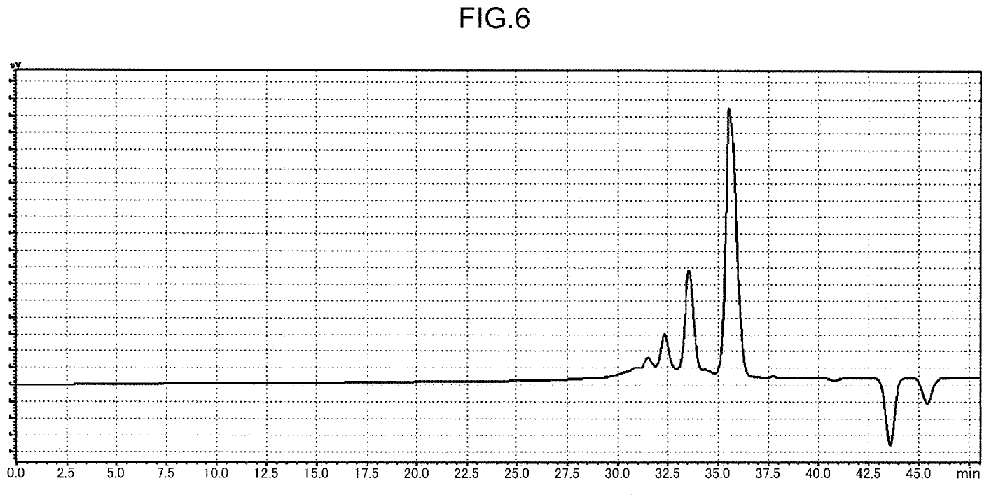

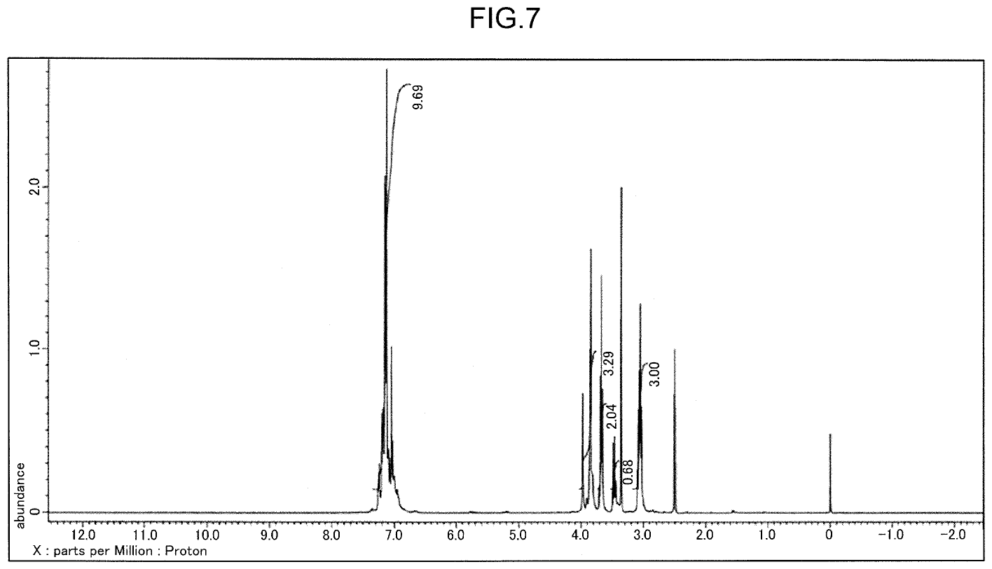

Into a flask equipped with a thermometer, a condenser, and a stirrer, 296 parts of 2-bromoethylbenzene (manufactured by Tokyo Chemical Industry Co., Ltd.), 70 parts of α,α′ dichloro-p-xylene (manufactured by Tokyo Chemical Industry Co., Ltd.), and 18.4 parts of methanesulfonic acid (manufactured by Tokyo Chemical Industry Co., Ltd.) were introduced, and the reaction was conducted at 130° C. for 8 hours. After being left to cool, the reaction mixture was neutralized with an aqueous sodium hydroxide solution, and subjected to extraction with 1200 parts of toluene, and the organic layer was washed with 100 parts of water five times. The solvent and excess 2-bromoethylbenzene were distilled off under heating and reduced pressure to obtain 160 parts of an olefin compound precursor (BEB-1) having a 2-bromoethylbenzene structure as a liquid resin (Mn: 538, Mw: 649). A GPC chart of the obtained compound is illustrated in FIG. 6. The repeating unit n calculated from the area % in the GPC chart was 1.7. A ¹H-NMR chart (DMSO-d6) of the obtained compound is illustrated in FIG. 7. Signals attributed to a bromoethyl group were observed at 2.95 to 3.15 ppm and 3.60 to 3.75 ppm on the ¹H-NMR chart.

### Synthesis Example 2

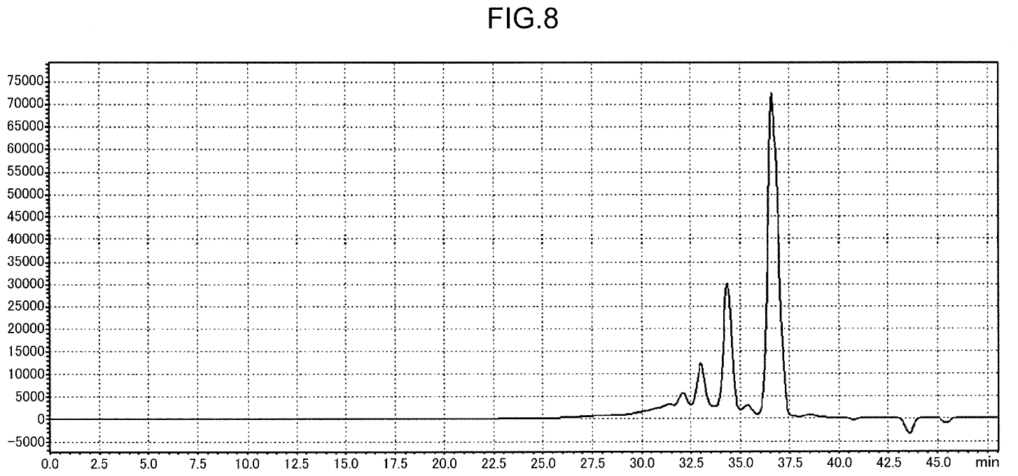

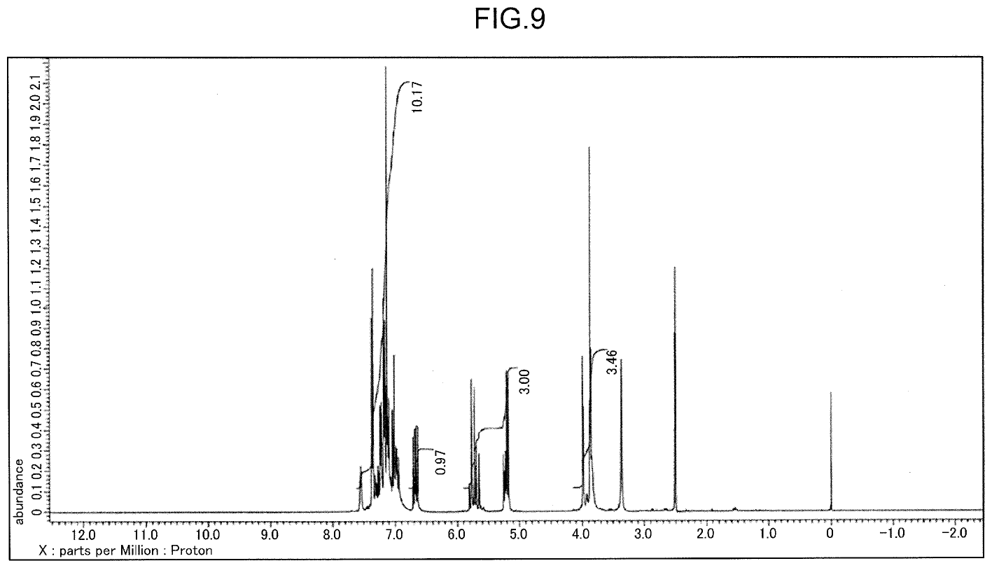

Next, 22 parts of BEB-1 obtained in Synthesis Example 1, 50 parts of toluene, 150 parts of dimethyl sulfoxide, 15 parts of water and 5.4 parts of sodium hydroxide were introduced into a flask equipped with a thermometer, a condenser, and a stirrer, and the reaction was conducted at 40° C. for 5 hours. After standing to cool, 100 parts of toluene was added, the organic layer was washed with 100 parts of water five times, and the solvent was distilled off under heating and reduced pressure to obtain 13 parts of a liquid olefin compound having a styrene structure as a functional group (Mn: 432, Mw: 575). A GPC chart of the obtained compound is illustrated in FIG. 8. The repeating unit n calculated from the area % in the GPC chart was 1.7. A ¹H-NMR data (DMSO-d6) of the obtained compound is illustrated in FIG. 9. Signals attributed to a vinyl group were observed at 5.10 to 5.30 ppm, 5.50 to 5.85 ppm, and 6.60 to 6.80 ppm on the ¹H-NMR chart.

The liquid olefin compound was referred to as hydrocarbon-based compound 1.

### (Styrenic Polymer (B))

Styrenic polymer 1: Hydrogenated styrenic thermoplastic elastomer (SEBS) (“Tuftec (registered trademark) H1517” manufactured by Asahi Kasei Corporation, number average molecular weight Mn 76000, solid at 25° C.)
Styrenic polymer 2: Hydrogenated methylstyrene (ethylene/butylene) methylstyrene block copolymer (V9827 manufactured by KURARAY CO., LTD., weight average molecular weight Mw: 92000, solid at 25° C.)
Styrenic polymer 3: Hydrogenated methylstyrene (ethylene/ethylene propylene) methylstyrene block copolymer (V9461 manufactured by KURARAY CO., LTD., weight average molecular weight Mw: 240000, solid at 25° C.)
Styrenic polymer 4: Hydrogenated styrene (ethylene propylene) styrene block copolymer (2002 manufactured by KURARAY CO., LTD., weight average molecular weight Mw: 54000, solid at 25° C.)
Styrenic polymer 5: Hydrogenated styrene isoprene styrene block copolymer (7125F manufactured by KURARAY CO., LTD., weight average molecular weight Mw: 99000, number average molecular weight Mn: 82000, solid at 25° C.)
Styrenic polymer 6: Styrene-(methylstyrene)-based block copolymer (FTR2140 manufactured by Mitsui Chemicals, Inc., weight average molecular weight Mw: 3230, solid at 25° C.)
Styrenic polymer 7: Styrenic polymer (FTR6125 manufactured by Mitsui Chemicals, Inc., weight average molecular weight Mw: 1950, number average molecular weight Mn: 1150, solid at 25° C.)

### (Other Styrenic Polymers)

Styrenic polymer 8: Liquid butadiene-styrene random copolymer (Ricon 181 manufactured by CRAY VALLEY, liquid at 25° C.)

### (Reactive Compound (C))

Polyphenylene ether (PPE) compound: OPE-2st 1200 (polyphenylene ether compound having vinylbenzyl group (ethenylbenzyl group) at terminal, manufactured by Mitsubishi Gas Chemical Company, Inc.)
Methacrylate compound: DCP (tricyclodecane dimethanol dimethacrylate, manufactured by SHIN-NAKAMURA CHEMICAL Co., Ltd.)
Epoxy compound: HP-7000 (dicyclopentadiene-type epoxy resin, manufactured by DIC Corporation)
Maleimide compound: MIR-5000 (manufactured by Nippon Kayaku Co., Ltd.)
Vinyl compound liquid at 25° C.: Styrene-butadiene-styrene copolymer, SBS type C (manufactured by Nippon Soda Co., Ltd.)

### (Flame Retardant)

Aromatic condensed phosphate ester: PX-200 (manufactured by DAIHACHI CHEMICAL INDUSTRY CO., LTD.) (Inorganic filler)
Silica particles: SC2050-MNU (vinylsilane treated silica, manufactured by ADMATECHS COMPANY LIMITED)

### Examples 1 to 14 and Comparative Examples 1 and 2

### [Preparation Method]

### (Resin Varnish)

First, the respective components, that is, resin components (hydrocarbon-based compound, styrenic polymer, reactive compound, and the like) were added to toluene at the blending proportion (parts by mass) presented in Table 1 so that the solid concentration was 50% by mass, and mixed. Depending on the sample, the reaction initiator, inorganic filler, and the like were added to the mixture, stirring was performed for 60 minutes, and then dispersion was performed using a bead mill to obtain a resin varnish.

### (Fabrication of Evaluation Sample)

Next, a metal foil with resin and an evaluation substrate (cured product of metal foil with resin) were obtained as follows.

The obtained varnish was applied to copper foil (MT18FL manufactured by Mitsui Mining & Smelting Co., Ltd., thickness: 1.5 μm) to have a thickness of 20 μm, and heated and dried at 100° C. for 2 minutes, thereby fabricating a metal foil with resin (copper foil with resin). Thereafter, two sheets of each obtained metal foil with resin were stacked and heated to a temperature of 220° C. at a rate of temperature rise of 3° C./min and heated and pressed under the conditions of 220° C., 120 minutes, and a pressure of 2 MPa, thereby obtaining an evaluation substrate 1 (cured product of metal foil with resin).

The metal foil with resin and evaluation substrates 1 (cured product of metal foil with resin) fabricated as described above were used to perform the evaluation by the following methods.

### Evaluation Test

### (Tackiness)

The copper foils with resin were stacked so that the resin surfaces faced each other, packed in an aluminum bag, and left at room temperature (20° C.) for 1 day, then the seal of the aluminum bag was opened, and it was examined whether the stacked copper foils with resin were released from each other. Regarding the evaluation, a case where the copper foils with resin could be neatly separated into the original two sheets and released was evaluated as “good”, and a case where the copper foils with resin were not neatly separated into the original two sheets and released and the resin on the copper foils with resin was damaged during release was evaluated as “poor”.

### (Dielectric Properties (Dielectric Loss Tangent))

The dielectric loss tangent (Df) of the evaluation substrate 1 (cured product of metal foil with resin) at 10 GHz was measured by the cavity perturbation method. Specifically, the dielectric loss tangent of the evaluation substrate at 10 GHz was measured using a network analyzer (N5230A manufactured by Keysight Technologies). The acceptance criterion in the present Example was Df≤0.0015.

### (Coefficient of Thermal Expansion)

An unclad substrate obtained by removing the copper foil from the evaluation substrate 1 (cured product of metal foil with resin) by etching was cut to have a length of 25 mm and a width of 5 mm. The cut unclad substrate was used as a test piece, and the dimensional change of the test piece was measured in a range of 20° C. to 320° C. at a probe distance of 15 mm and a tensile load of 50 mN using a TMA instrument (TMA6000 manufactured by SII NanoTechnology Inc.). From this dimensional change, the average coefficient of thermal expansion in the range of 50° C. to 260° C. was calculated, and this average coefficient of thermal expansion was taken as the coefficient of thermal expansion (CTE: ppm/° C.). The acceptance criterion in the present Example was 200 ppm/° C. or less.

### (Thermal Decomposition Temperature)

An unclad substrate obtained by removing the copper foil from the evaluation substrate 1 (cured product of metal foil with resin) by etching was cut to have a diameter of 5 mm. The thermogravimetric analysis was performed on this cut unclad substrate as a test piece from 30° C. to 500° C. at a rate of temperature rise of 10° C./min using a TGA instrument (STA7200RV manufactured by Hitachi High-Tech Science Corporation). The temperature at which the weight decreased by 5% was evaluated as the thermal decomposition temperature. The acceptance criterion in the present Example was 400° C. or more.

The results are presented in Table 1.

TABLE 1

| | | Example | | | | | | | |
|---|---|---|---|---|---|---|---|---|---|
| Division | Substance number | 1 | 2 | 3 | 4 | 5 | 6 | 7 | 8 |
| Hydrocarbon-based | Hydrocarbon-based | 50 | 30 | 50 | 50 | 50 | 50 | 50 | 50 |
| compound (A) | compound 1 | | | | | | | | |
| Styrenic polymer | Styrenic polymer 1 | 50 | 70 | | | | | | |
| (B) | Styrenic polymer 2 | | | 50 | | | | | |
| | Styrenic polymer 3 | | | | 50 | | | | |
| | Styrenic polymer 4 | | | | | 50 | | | |
| | Styrenic polymer 5 | | | | | | 50 | | |
| | Styrenic polymer 6 | | | | | | | 50 | |
| | Styrenic polymer 7 | | | | | | | | 50 |
| Other styrenic | Styrenic polymer 8 | | | | | | | | |
| polymers | | | | | | | | | |
| Reactive compound | PPE compound | | | | | | | | |
| (C) | Methacrylate compound | | | | | | | | |
| | Epoxy compound | | | | | | | | |
| | Maleimide compound | | | | | | | | |
| | Vinyl compound | | | | | | | | |
| Flame retardant | Condensed phosphate | | | | | | | | |
| | ester | | | | | | | | |
| Inorganic filler | Spherical silica | | | | | | | | |
| Evaluation | | | | | | | | | |
| Tackiness | | good | good | good | good | good | good | good | good |
| Dielectric loss | | 0.0011 | 0.0010 | 0.0011 | 0.0011 | 0.0011 | 0.0011 | 0.0011 | 0.0011 |
| tangent (10 GHz) | | | | | | | | | |
| Coefficient of | ppm/° C. | 125 | 174 | 125 | 125 | 125 | 125 | 125 | 125 |
| thermal expansion | | | | | | | | | |
| Thermal decomposition | ° C. | 413 | 400 | 413 | 413 | 413 | 413 | 413 | 413 |
| temperature | | | | | | | | | |

| | |
|---|---|
| Example | Comparative Example |

| Division | Substance number | 9 | 10 | 11 | 12 | 13 | 14 | 1 | 2 |
|---|---|---|---|---|---|---|---|---|---|
| Hydrocarbon-based | Hydrocarbon-based | 35 | 45 | 40 | 40 | 40 | 50 | | 50 |
| compound (A) | compound 1 | | | | | | | | |
| Styrenic polymer | Styrenic polymer 1 | 50 | 50 | 50 | 50 | 50 | 50 | 50 | |
| (B) | Styrenic polymer 2 | | | | | | | | |
| | Styrenic polymer 3 | | | | | | | | |
| | Styrenic polymer 4 | | | | | | | | |
| | Styrenic polymer 5 | | | | | | | | |
| | Styrenic polymer 6 | | | | | | | | |
| | Styrenic polymer 7 | | | | | | | | |
| Other styrenic | Styrenic polymer 8 | | | | | | | | 50 |
| polymers | | | | | | | | | |
| Reactive compound | PPE compound | 15 | | | | | | 50 | |
| (C) | Methacrylate compound | | 5 | | | | | | |
| | Epoxy compound | | | 10 | | | | | |
| | Maleimide compound | | | | 10 | | | | |
| | Vinyl compound | | | | | 10 | | | |
| Flame retardant | Condensed phosphate | | | | | | 10 | | |
| | ester | | | | | | | | |
| Inorganic filler | Spherical silica | | | | | | 100 | | |
| Evaluation | | | | | | | | | |
| Tackiness | | good | good | good | good | good | good | good | poor |
| Dielectric loss | | 0.0014 | 0.0013 | 0.0015 | 0.0015 | 0.0011 | 0.0009 | 0.0018 | N/A |
| tangent (10 GHz) | | | | | | | | | |
| Coefficient of | ppm/° C. | 178 | 120 | 123 | 115 | 135 | 45 | 348 | N/A |
| thermal expansion | | | | | | | | | |
| Thermal decomposition | ° C. | 400 | 415 | 418 | 420 | 408 | 463 | 349 | N/A |
| temperature | | | | | | | | | |

### DISCUSSION

As is clear from the results presented in Table 1, it was confirmed that the resin composition of the present invention affords a cured product that can exhibit suppressed tackiness and exhibits low dielectric properties, low thermal expansion properties, and heat resistance.

In particular, in Example 14 in which a flame retardant and an inorganic filler are added, the cured product exhibits extremely excellent heat resistance and low thermal expansion properties as well as excellent low dielectric properties. In Examples 12 and 14, the thermal decomposition temperature is higher.

On the other hand, in the case of resin composition of Comparative Example 1 in which the hydrocarbon-based compound (A) of the present invention is not contained, the cured product does not exhibit low dielectric properties, has a high coefficient of thermal expansion, and is also inferior in heat resistance. In the case of resin composition of Comparative Example 2 in which a liquid styrenic polymer is contained instead of the styrenic polymer (B) of the present invention, the tackiness cannot be suppressed and an evaluation substrate cannot be fabricated.

This application is based on Japanese Patent Application No. 2021-83148 filed on May 17, 2021, the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

The present invention has wide industrial applicability in technical fields such as electronic materials, electronic devices, and optical devices.

1. A resin composition comprising:
a hydrocarbon-based compound (A) represented by the following Formula (1): 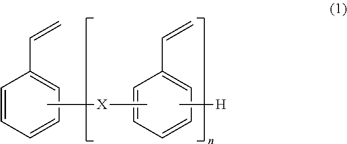
wherein X represents a hydrocarbon group having 6 or more carbon atoms and containing at least one selected from an aromatic cyclic group or an aliphatic cyclic group, and n represents an integer from 1 to 10; and
a styrenic polymer (B) that is solid at 25° C. and is different from the hydrocarbon-based compound (A).

2. The resin composition according to claim 1, wherein the hydrocarbon-based compound (A) includes a hydrocarbon-based compound (A1) represented by the following Formula (2): 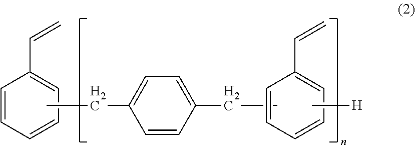
wherein n represents an integer from 1 to 10.

3. The resin composition according to claim 1, wherein the styrenic polymer (B) includes a hydrogenated styrenic copolymer.

4. The resin composition according to claim 3, wherein the hydrogenated styrenic copolymer includes at least one selected from the group consisting of a hydrogenated methylstyrene (ethylene/butylene) methylstyrene block copolymer, a hydrogenated methylstyrene (ethylene-ethylene/propylene) methylstyrene block copolymer, a hydrogenated styrene isoprene block copolymer, a hydrogenated styrene isoprene styrene block copolymer, a hydrogenated styrene (ethylene/butylene) styrene block copolymer, and a hydrogenated styrene (ethylene-ethylene/propylene) styrene block copolymer.

5. The resin composition according to claim 1, wherein a content of the hydrocarbon-based compound (A) is 20 to 80 parts by mass with respect to 100 parts by mass of a total mass of the hydrocarbon-based compound (A) and the styrenic polymer (B).

6. The resin composition according to claim 1, comprising a reactive compound (C) that reacts with at least one of the hydrocarbon-based compound (A) or the styrenic polymer (B).

7. The resin composition according to claim 1, wherein the reactive compound (C) includes at least one selected from the group consisting of a maleimide compound, an epoxy compound, a methacrylate compound, an acrylate compound, a vinyl compound that is liquid at 25° C., a cyanate ester compound, an active ester compound, an allyl compound, a benzoxazine compound, a phenol compound, and a polyphenylene ether compound.

8. The resin composition according to claim 1, wherein a content of the styrenic polymer (B) is 5 to 50 parts by mass with respect to 100 parts by mass of a sum of the hydrocarbon-based compound (A), the styrenic polymer (B), and the reactive compound (C).

9. The resin composition according to claim 1, wherein a content of the reactive compound (C) is 1 to 40 parts by mass with respect to 100 parts by mass of a sum of the hydrocarbon-based compound (A), the styrenic polymer (B), and the reactive compound (C).

10. The resin composition according to claim 1, comprising an inorganic filler.

11. The resin composition according to claim 1, comprising a phosphorus-based flame retardant.

12. A prepreg comprising:
the resin composition according to claim 1 or a semi-cured product of the resin composition; and
a fibrous base material.

13. A film with resin comprising:
a resin layer containing the resin composition according to claim 1 or a semi-cured product of the resin composition; and
a support film.

14. A metal foil with resin comprising:
a resin layer containing the resin composition according to claim 1 or a semi-cured product of the resin composition; and
a metal foil.

15. A metal-clad laminate comprising:
an insulating layer containing a cured product of the resin composition according to claim 1; and
a metal foil.

16. A wiring board comprising:
an insulating layer containing a cured product of the resin composition according to claim 1; and
wiring.

17. A metal-clad laminate comprising:
an insulating layer containing a cured product of the prepreg according to claim 12; and
a metal foil.

18. A wiring board comprising:
an insulating layer containing a cured product of the prepreg according to claim 12; and
wiring.
